(19) United States
(12) Patent Application Publication
(10) Pub. No.: US 2012/0286419 A1
(43) Pub. Date: Nov. 15, 2012

(54) SEMICONDUCTOR PACKAGE WITH INTERPOSER BLOCK THEREIN

(75) Inventors: Yong Tae Kwon, Suwon-si (KR); Gi Jo Jung, Chungcheongbuk-do (KR)

(73) Assignee: NEPES CORPORATION, Chungcheongbuk-do (KR)

(21) Appl. No.: 13/457,165

(22) Filed: Apr. 26, 2012

(30) Foreign Application Priority Data
May 13, 2011 (KR) 10-2011-0044861

(51) Int. Cl. H01L 25/07; H01L 21/50; H01L 23/48

(52) U.S. Cl. 257/737; 257/774; 438/126; 257/E25.018; 257/E23.011; 257/E21.499

(57) ABSTRACT

A semiconductor package substrate is provided. The package substrate includes a mold base and an interposer block embedded in the mold base, said interposer block having a plurality of vertical conductive lines therein. A metallization layer is formed on the surface of the interposer block or the mold base, said metallization layer being electrically connected to at least one of the vertical conductive lines. A semiconductor chip may be mounted on or embedded in the mold base.

### TECHNICAL FIELD

The present invention relates to a semiconductor package, and more particularly, to a new semiconductor package with an interposer block therein.

### BACKGROUND ART

A semiconductor component includes a semiconductor substrate containing various semiconductor devices and integrated circuits. Typically, the semiconductor substrate is in the form of a semiconductor die, that has been singulated from a semiconductor wafer. For example, a chip scale semiconductor component includes a semiconductor die provided with support and protective elements, and a signal transmission system. Semiconductor components can also include multiple semiconductor substrates in a stacked or planar array.

It is well known that the consumers of the next generation electronic devices are demanding increased functions and features that are packed in a smaller size, consuming less power, and costing less than the earlier generation. Semiconductor device manufacturers are responding by incorporating improved three dimensional packaging technologies, such as systems in package (SiP), Multi-Chip Packages (MCPs), Package-on-Package (PoP), and similar others, that provide vertical stacking of one or more dies and/or packages that are integrated to operate as one semiconductor device.

However, a high functional semiconductor package needs an additional package substrate to embed semiconductor chips or devices therein, and also requires to have a complicated wiring and metallization structure for connecting devices thereto.

In particular, 3-dimensional package with vertical stacked structure should need a new design or layout for satisfying both vertical interconnection and semiconductor device mounting issues. Current used package substrates (such as a Printed Circuit Board) are difficult to minimize the size and pitch of vertical through via therein, and are resultantly not suitable for a slim and small package.

Meanwhile, a silicon wafer with through holes therein has a limit to vary the structure of a package and to decrease the size of a package.

### DISCLOSURE

### Technical Problem

Therefore, the present invention is directed to provide a new semiconductor package for a 3-dimensional stack package.

Another object of the present invention is to provide a light, thin, short and small semiconductor package.

Still another object of the present invention is to provide a semiconductor package with enhanced operation characteristics and to be easily fabricated through simple process.

### Technical Solution

In accordance with an aspect of the present invention, the present invention provides a semiconductor package, comprising: a mold base; an interposer block embedded in the mold base, said interposer block having a plurality of vertical conductive lines therein; a metallization layer on the surface of the interposer block or the mold base, said metallization layer being electrically connected to at least one of the vertical conductive lines; and a semiconductor chip mounted on the mold base, said semiconductor chip being electrically connected to the metallization layer, wherein the top and the bottom of the interposer block are on the same plane as the top and the bottom of the mold base.

In accordance with another aspect of the present invention, the present invention provides a semiconductor package, comprising: a mold base; an interposer block embedded in the mold base, said interposer block having a plurality of vertical conductive lines therein; a metallization layer on the surface of the interposer block or the mold base, said metallization layer being electrically connected to at least one of the vertical conductive lines; a semiconductor chip embedded in the mold base, said semiconductor chip being electrically connected to the metallization layer; and a bump electrically connected to at least one of the vertical conductive lines.

In accordance with further another aspect of the present invention, the present invention provides a method a semiconductor package substrate, comprising:

a polymer resin base; a silicon block embedded in the mold base, said block having a plurality of vertical conductive lines therein; and a metallization layer on the surface of the block or the base, wherein the metallization layer being electrically connected to at least one of the vertical conductive lines.

In accordance with still another aspect of the present invention, the present invention provides a method for fabricating a semiconductor package substrate, comprising: preparing an interposer block having a plurality of vertical conductive lines therein, according to the following steps: a) forming a plurality of vertical holes in a semiconductor wafer, b) filling conductive material into the holes, and c) cutting the wafer into each individual block; arranging the interposer block on a carrier substrate; forming a molding part on the carrier substrate; and removing the carrier substrate from the interposer block and the molding part.

According to the present invention, freedom of design for a semiconductor package can be improved. Moreover, the present invention allows a thin and small semiconductor package with shorter signal line, and resultantly enhanced operation of a semiconductor package. Densely arranged vertical interconnections and fine pitch metallization in a semiconductor package of the present invention realizes high speed operation and reduced package size, resulting in slimming of various mobile electronic devices.

### DESCRIPTION OF DRAWINGS

The above and other features and advantages of the present invention will become more apparent to those of ordinary skill in the art by describing in detail preferred embodiments thereof with reference to the attached drawings in which:

FIG. 1 shows a plan view of a package substrate in accordance with a preferred embodiment of the present invention.

FIG. 2 is a sectional view of the package substrate.

FIGS. 3 to 12 are sectional views showing steps of a fabrication process in accordance with an embodiment of the present invention.

FIG. 13 is a sectional view of a semiconductor package in accordance with an embodiment of the present invention.

FIG. 14 is a sectional view of a semiconductor package in accordance with another embodiment of the present invention.

FIG. 15 is a plan view of a semiconductor package in accordance with still another embodiment of the present invention.

FIG. 16 is a sectional view of the semiconductor package of FIG. 15.

FIG. 17 is a sectional view of a stacked semiconductor package.

FIG. 18 is a sectional view of a semiconductor package in accordance with further another embodiment of the present invention.

### MODE FOR INVENTION

The present invention will now be described more fully hereinafter with reference to the accompanying drawings, in which preferred embodiments of the invention are shown. The present invention relates to a new substrate for a 3-dimensional semiconductor package. The substrate may have various semiconductor devices mounted on one or both surfaces of it and can have a semiconductor device or other electronic device embedded therein, so that a semiconductor package may have a variety of structure and the size of the package can be remarkably reduced.

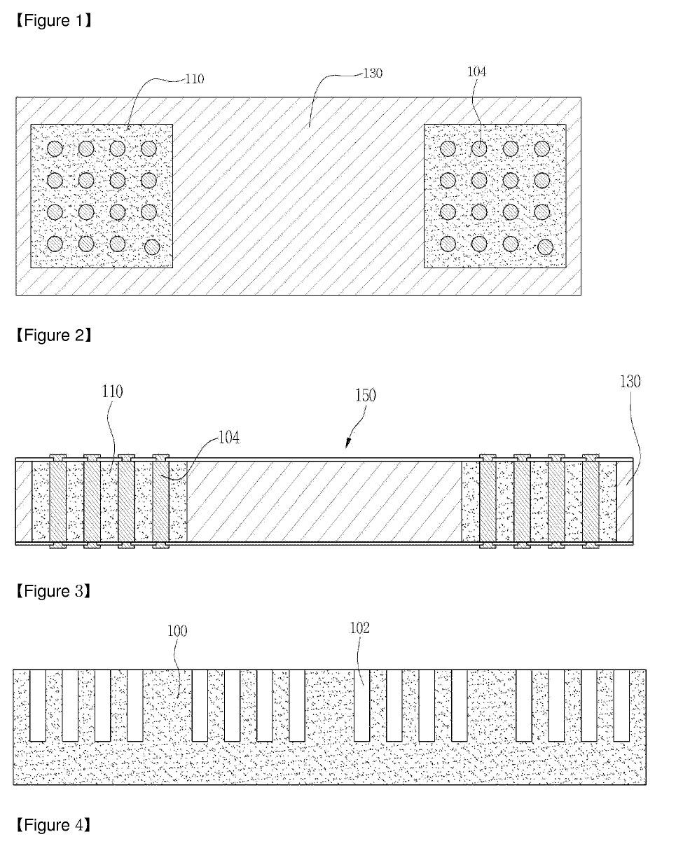

FIGS. 1 and 2 show a semiconductor package substrate (150) in accordance with the present invention. Interposer blocks (110) are embedded in a mold base (130). The mold base may be formed in a desired geometrical figure, and the interposer block can have a diverse structure needed for a package. The interposer block may include a plurality of sub blocks. In this regard, the sub blocks in the mold base may be arranged apart (or spaced apart) form one another.

The interposer block embedded in the mold base includes a plurality of vertical conductive lines (104) therein. The conductive line can be formed, for example, by forming a through hole in the interposer block and filling conductive material into the through hole. The diameter of the conductive line and the distance between neighboring conductive lines may be varied depending on a final package design rule. Minimizing the diameter and the distance of the conductive line allows an interposer block with fine pitch interconnections therein.

The interposer block or the mold base may have a metallization layer and/or an interlayer dielectric on a surface thereof.

The top and the bottom of the interposer block are on the same plane as the top and the bottom of the mold base. The interposer block and the mold base may function as a slim substrate or an interposer for a semiconductor package and can realize a light, thin, short and small sized semiconductor package.

A package substrate according to the present invention may have a semiconductor chip mounted on the mold base and electrically connected to the conductive line or the metallization layer. The details are described later.

The mold base may be formed using a polymer resin, and the interposer block is preferably to be formed using semiconductor material (i.e. silicon). Independently prepared interposer blocks are combined with a mold base to be one body for a package substrate. Combination of different interposer blocks and mold base allows freedom of design for a semiconductor package. The package substrate according to the present invention is much easier to optimize the size of a vertical conductive line than a PCB (printed circuit board) and thus can be substituted for a PCB to fabricate a semiconductor package. Moreover, the package substrate can solve the critical issue in a PCB package due to CTE (Coefficient of Thermal Expansion) difference between a (polymer resin based) PCB substrate and a (Si based) semiconductor chip mounted on a PCB.

Referring FIGS. 3 to 12, fabrication process of a package substrate in accordance with the present invention is described.

The package substrate of the present invention includes a molding part as a base and at least one interposer block as a vertical interconnection.

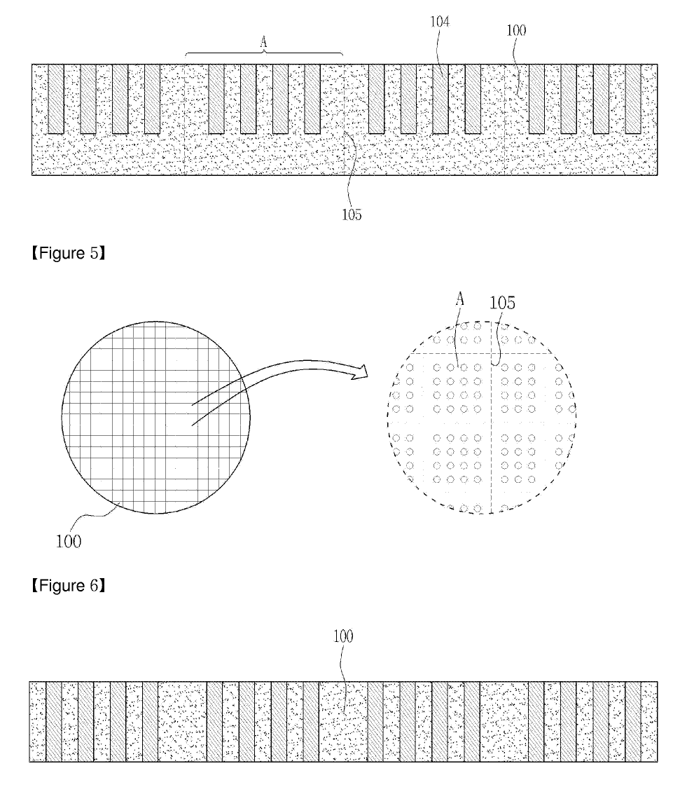

Interposer blocks can be independently prepared in wafer level process. Firstly, as shown in FIG. 3, a plurality of holes (102) is formed in a wafer (100), using well known technology, such as reactive ion etching, inductively coupled plasma, or wet etching. Next, conductive material is filled into the holes using such as electroplating to form vertical conductive lines (104) (as shown in FIG. 4).

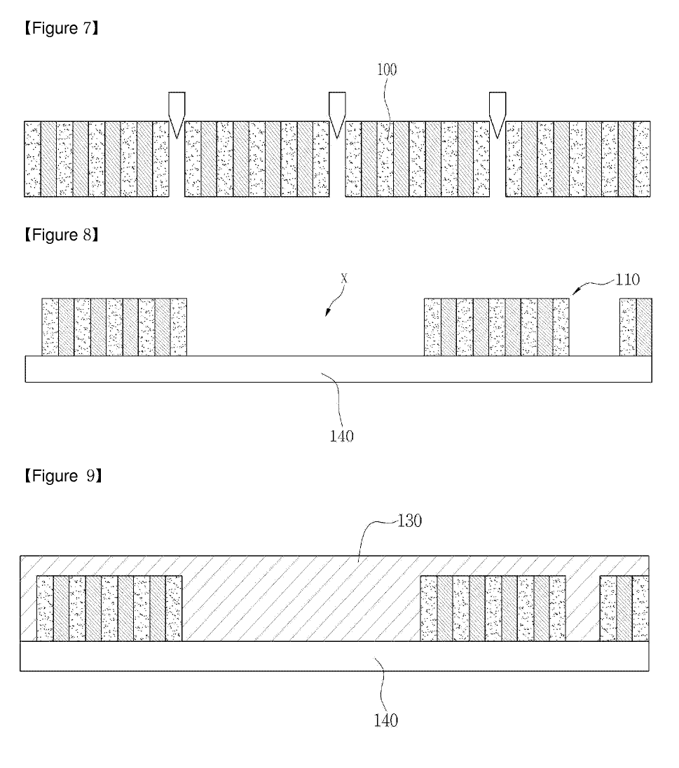

Vertical conductive lines can be divided into individual units by sawing line (105). For example, as shown in FIG. 5, a region (A) divided by sawing line (105) in a wafer (100) corresponds to an individual unit (that is, one interposer block).

Divided blocks in a wafer may have different size or shape, and may have different number or arrangement of holes formed therein. In this way, various interposer blocks in one wafer can be fabricated efficiently in a single process. Also, interposer blocks may be tested in wafer level to be selected as good block, which can reduce defects of a package substrate and a final semiconductor package.

After forming conductive lines, the bottom surface of the wafer is grinded to expose the lower part of conductive lines (FIG. 6). In this process, the wafer may be further grinded to be thinner. And then, the wafer is sawed into individual blocks (FIG. 7).

Next, prepared interposer blocks (110) are arranged on a wafer or a carrier substrate (140) (FIG. 8). The arrangement and the number of the interposer block may be varied depending on the design of a final package. A plurality of blocks can be spaced apart with one another. A semiconductor chip or other electronic device may be further arranged in the space (X) between neiboring blocks. The added semiconductor chip in the space (X) corresponds to an embedded component in a mold base (as further described later).

After arranging interposer blocks, a mold base (130) is formed on the carrier substrate (FIG. 9). And then, the upper surface of the mold base is grinded to be the same height as the top surface of the interposer block. Consequently, the substrate according to the present invention has an assembled structure of a mold base and embedded interposer blocks.

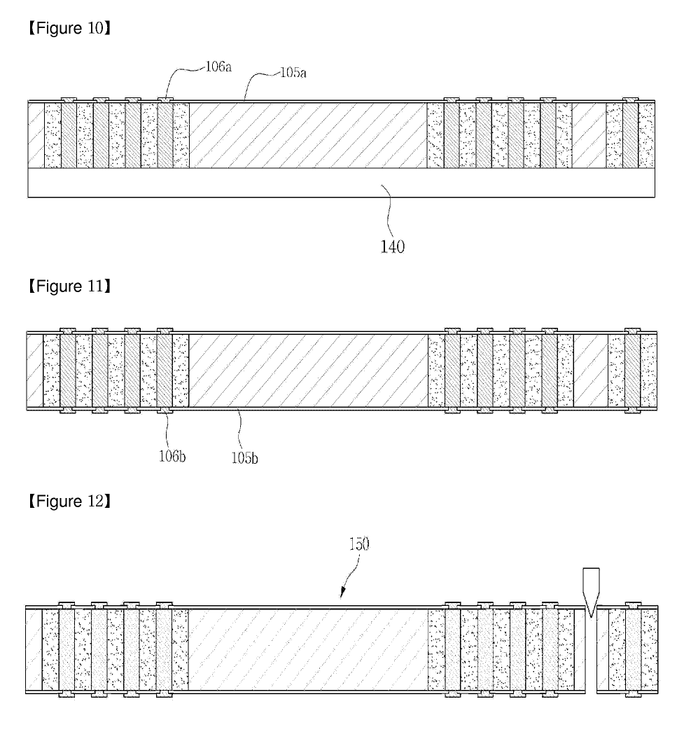

Next, an insulation layer is formed on the mold base and the interposer block, and an electrical pads or a metallization layer (106a) is formed to be electrically connected to the conductive line (FIG. 10). The metallization layer functions as an interconnection between the conductive line and a device mounted on the mold base. After removing the carrier substrate from the mold base and the interposer block, an insulation layer (105b) and a metallization layer (106b) are formed on the other side of the mold base and the interposer block (FIG. 11). The bottom surface of the mold base and the interposer block may be grinded to be thinner.

Finally, the mold base is sawed into individual units (FIG. 12), and the semiconductor substrate (150) of the present invention is completed. The substrate has a thin structure of a mold base and embedded blocks with vertical conductive lines therethrough, and can be used as a package substrate or an interposer for various semiconductor systems. The conductive line formed in the interposer block allows minimized size and high density of vertical interconnection of the substrate. Consequently, a final semiconductor package can have enhanced operation characteristic, and a light and slim sized system package can be realized.

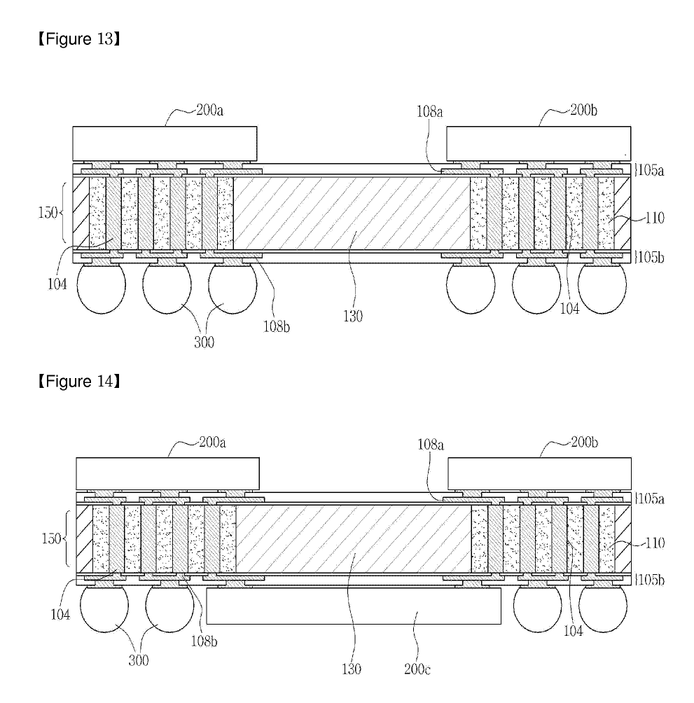

FIG. 13 shows a semiconductor package according to an example of the present invention. In the package, two semiconductor chips (200a, 200b) are mounted on the top surface of a package substrate (150), and a plurality of interposer blocks (110) is spaced apart in a mold base (130) of the substrate. On the top and bottom surfaces of the substrate, insulation layers (105a, 105b) and metallization layers (108a, 108b) are formed, respectively. The insulation layer include may include a plurality of sub layers. One end of the metallization layer is electrically connected to a conductive line (104) and the other end is redistributed to the semiconductor chip for interconnection between the chip and the conductive line. Thus, the semiconductor chips (200a, 200b) can be electrically connected via the metallization layer (108a) to the conductive line (104) of the interposer block. Below the bottom surface of the substrate, bumps (300) are formed to be electrically connected to the conductive line. The metallization layer (108b) on the bottom of the substrate may interconnect the bump and the conductive line.

In the semiconductor package of the present invention, the arrangement of an interposer block and a semiconductor chip doesn't have to be fixed. Change of the patterning of the metallization layer enables a semiconductor chip at any part of the substrate to be electrically connected to the conductive line. The number or the size of semiconductor chips to be mounted on the substrate is not limited, and various devices can be mounted on the substrate to be assembled into a high quality semiconductor module or system.

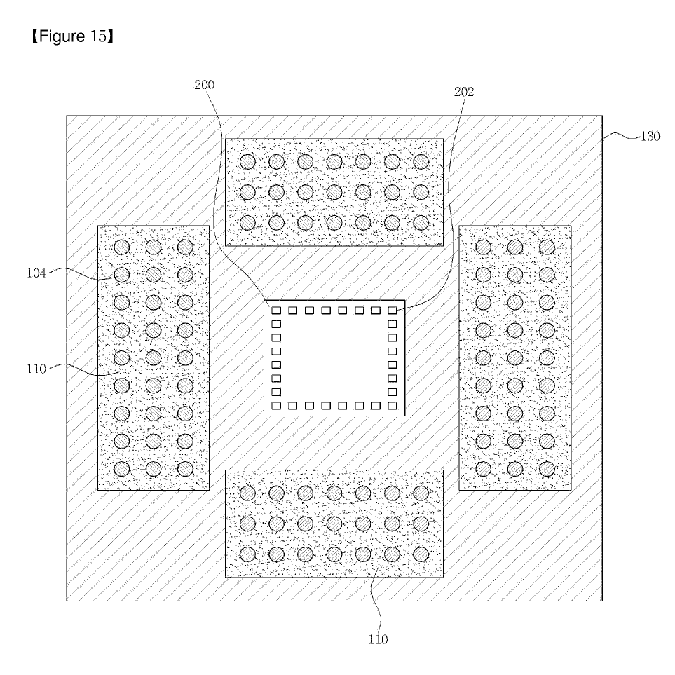

FIG. 14 shows a semiconductor package according to another example of the present invention. In the package, two semiconductor chips (200a, 200b) are mounted on the top surface of a package substrate (150) similarly to the former example, and a further semiconductor chip (200c) is mounted on the bottom surface of the substrate. The semiconductor chips on the top and bottom surfaces are respectively electrically connected via metallization layers (108a, 108b) to the vertical conductive line (104) of the interposer block. In this way, the substrate with semiconductor chips mounted on both sides thereof is suitable for a system-in-package, a stacked package, or other type of functional packages. In particular, since semiconductor chips on the top and the bottom surfaces of the substrate send or receive electrical signals via vertical conductive lines (104), operating characteristic of the chips will be remarkably enhanced.

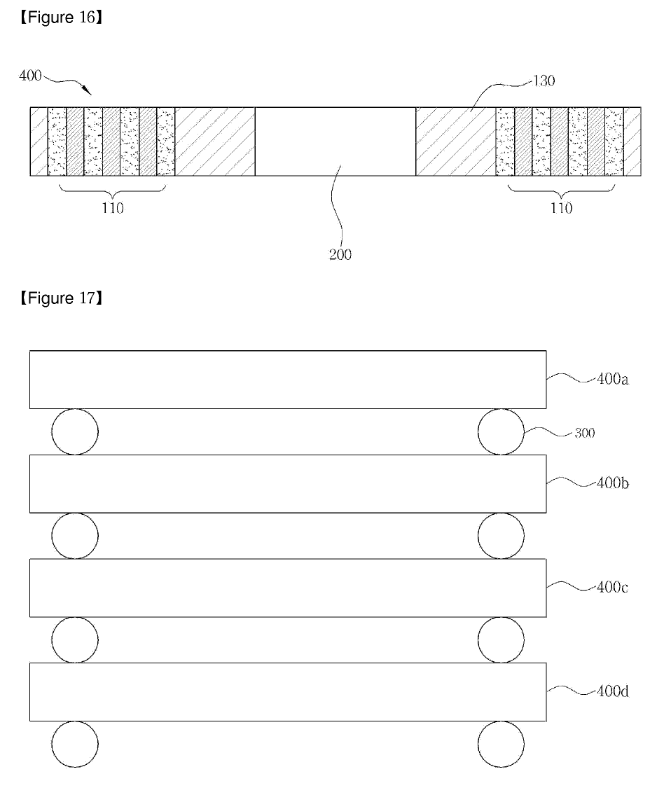

FIG. 15 shows a semiconductor package according to further another example of the present invention. In the package, a plurality of interposer blocks (110) is spaced apart in a mold base (130) of the package substrate. A semiconductor chip (200) is embedded in the mold base, similarly to the interposer block (as shown in FIG. 16). The semiconductor chip is arranged in the center of the mold base, and the interposer blocks are arranged around the semiconductor chip. The interposer blocks surrounding the semiconductor chip may be electrically connected to electrode pad (202) of the semiconductor chip, by connecting the pads and conductive lines (104) via a metallization layer (as described in the previous examples.

In this way, wirings of the semiconductor chip in mold base can spread out to the interposer blocks, resulting in a fan-out package. Moreover, since the interposer blocks and the semiconductor chip in the mold base form a single package structure (400) without an additional package substrate, a small and slim sized package can be realized. Furthermore, electric or signal line length of a semiconductor chip in the package becomes shorter, and resultantly high speed operation of a semiconductor system or package can be achieved.

The package with embedded semiconductor chip therein is suitable for stacking multi packages. As shown in FIG. 17, packages (400a, 400b, 400c, 400d) with embedded semiconductor chip therein are vertically stacked and are connected to each other via bumps (300). The stacked structure allows high quality package such as multi functional device or system IC.

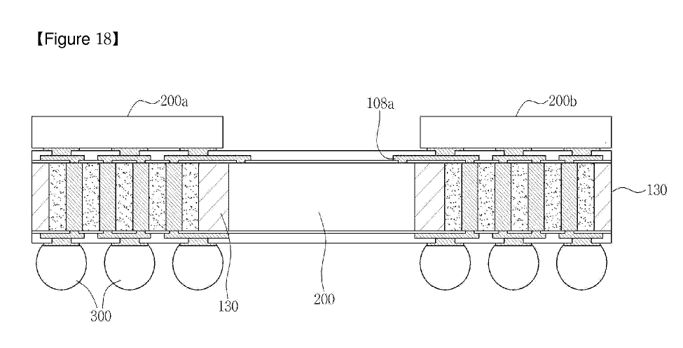

FIG. 18 shows a semiconductor package according to further another example of the present invention. This package includes an embedded semiconductor chip (200) in mold base and mounted semiconductor chips (200a, 200b) on mold base. The embedded semiconductor chip and the mounted semiconductor chips (200a, 200b) may be electrically connected via a metallization layer (108a) to a conductive line of the interposer block (130). Since a plurality of semiconductor chips is included in and on the package without an additional package substrate, the package is efficient to make a 3 dimensional system-in-package for mobile electronics such as a smart phone or a mobile display.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

1. A semiconductor package, comprising:
a mold base;
an interposer block embedded in the mold base, said interposer block having a plurality of vertical conductive lines therein;
a metallization layer on the surface of the interposer block or the mold base, said metallization layer being electrically connected to at least one of the vertical conductive lines; and
a semiconductor chip mounted on the mold base, said semiconductor chip being electrically connected to the metallization layer,
wherein the top and the bottom of the interposer block are on the same plane as the top and the bottom of the mold base,.

2. The semiconductor package of claim 1, wherein the mold base include a first interposer block and a second interposer block being arranged apart from each other, and the semiconductor chip is electrically connected to the first interposer block or the second interposer block.

3. The semiconductor package of claim 1, wherein a first semiconductor chip mounted on the top surface of the mold base and a second semiconductor chip mounted on the bottom surface of the mold base

4. The semiconductor package of claim 1, further comprising a bump electrically connected to at least one of the vertical conductive lines.

5. A semiconductor package, comprising:
a mold base;
an interposer block embedded in the mold base, said interposer block having a plurality of vertical conductive lines therein;
a metallization layer on the surface of the interposer block or the mold base, said metallization layer being electrically connected to at least one of the vertical conductive lines;
a semiconductor chip embedded in the mold base, said semiconductor chip being electrically connected to the metallization layer; and
a bump electrically connected to at least one of the vertical conductive lines.

6. The semiconductor package of claim 5, wherein the semiconductor chip is embedded in the center part of the mold base, and the interposer block includes sub blocks arranged to the side of the semiconductor chip.

7. The semiconductor package of claim 5, further comprising another semiconductor chip mounted on the mold base, said semiconductor chip being electrically connected to the interposer block.

8. A semiconductor package substrate, comprising:
a polymer resin base;
a silicon block embedded in the mold base, said block having a plurality of vertical conductive lines therein; and
a metallization layer on the surface of the block or the base,
wherein the metallization layer being electrically connected to at least one of the vertical conductive lines.

9. The semiconductor package substrate of claim 8, wherein the silicon block includes sub blocks embedded in the polymer resin base, said sub blocks being arranged apart from one another.

10. The semiconductor package substrate of claim 8, wherein the sub blocks are of different sizes and have different numbers of vertical conductive lines therein.

11. A method for fabricating a semiconductor package substrate, comprising:
preparing an interposer block having a plurality of vertical conductive lines therein, according to the following steps;
a) forming a plurality of vertical holes in a semiconductor wafer,
b) filling conductive material into the holes, and
c) cutting the wafer into each individual block
arranging the interposer block on a carrier substrate;
forming a molding part on the carrier substrate; and
removing the carrier substrate from the interposer block and the molding part.
